(19) United States
(12) Patent Application Publication
(10) Pub. No.: US 2018/0116045 A1
(43) Pub. Date: Apr. 26, 2018

(54) HEAT CONDUCTIVE ALD-COATING IN AN ELECTRICAL DEVICE

(71) Applicant: PICOSUN OY, Espoo (FI)

(72) Inventors: Juhana KOSTAMO, Espoo (FI); Tero LEHTO, Masala (FI); Markku KÄÄRIÄ, Espoo (FI); Ossi HÄMEENOJA, Salo (FI); Jyri SALMINEN, Salo (FI)

(21) Appl. No.: 15/558,656

(22) PCT Filed: Mar. 17, 2015
(86) PCT No.: PCT/FI2015/050177

§ 371 Date: Sep. 15, 2017

(51) Int. Cl. H05K 1/02; C23C 16/06; C23C 16/455

(52) U.S. Cl. CPC H05K 1/0203; C23C 16/45527; C23C 16/06

(57) ABSTRACT

A method for providing a heat conductive coating on a surface of a substrate, and a heat conductive coating, includes depositing at least one thin continuous layer of a first material by ALD; wherein the first material has a lower heat conductivity than the substrate.

### FIELD

The aspects of the disclosed embodiments generally relate to atomic layer deposition (ALD). More particularly, the aspects of the disclosed embodiments relate to providing a heat conductive coating by means of ALD.

### BACKGROUND

This section illustrates useful background information without admission of any technique described herein representative of the state of the art.

Electronic components produce heat when in use. The size of modern electronic devices requires efficient heat transfer arrangements in order to transfer heat from the hot components and reduce risk of overheating. Furthermore, the heat needs to be transferred and dissipated in a controlled manner in order to avoid the surface temperature of the electronic device becoming too high for example in certain regions. Efficient heat transfer is also required inside electronic components, such as microprocessors, and for example in lightning devices using e.g. light emitting diodes.

As the size of the electronic devices, for example thickness thereof, is reduced, the heat transfer arrangements need to be effective. Known arrangements, such as using heat transfer tape, have proven less than optimal for controlled heat transfer and dissipation.

### SUMMARY

According to a first example aspect of the disclosed embodiments there is provided a method for providing a heat conductive coating on a surface of a substrate, comprising

depositing on the surface of the substrate at least one thin continuous layer of a first material by ALD; wherein

the first material has a lower heat conductivity than the substrate.

The method may further comprise depositing at least one thin continuous layer of a second material by ALD on the at least one layer of a first material.

The method may further comprise depositing alternating layers of the first and the second material.

The thin continuous layer of the first material and/or the second material may be amorphous.

The substrate may comprise material of high thermal conductivity.

The first and/or the second material may comprise amorphous metal oxides.

The first and/or the second material may comprise material chosen from a group comprising aluminum, magnesium, hafnium, titanium, tantalum and zirconium.

The first material and/or the second material may be chosen from a group comprising aluminum oxide, magnesium oxide, hafnium oxide, titanium oxide, tantalum oxide and zirconium oxide.

The thickness of the coating may be up to 250 nm.

According to a second example aspect of the disclosed embodiments there is provided a heat conductive coating, comprising

at least one thin continuous layer of a first material deposited by ALD on a surface of a substrate; wherein

the first material has a lower heat conductivity than the substrate.

The coating may further comprise at least one thin continuous layer of a second material deposited by ALD on the at least one layer of a first material,.

The coating may further comprise alternating layers of the first and the second material deposited by ALD.

The thin continuous layer of the first material and/or the second material may be amorphous.

The first and/or the second material may comprise amorphous metal oxides.

The first and/or the second material may comprise material chosen from a group comprising aluminum, magnesium, hafnium, titanium, tantalum and zirconium.

The first material and/or the second material may be from a group comprising aluminum oxide, magnesium oxide, hafnium oxide, titanium oxide, tantalum oxide and zirconium oxide.

The thickness of the coating may be up to 250 nm.

According to a third example aspect of the disclosed embodiments there is provided a heat transfer apparatus, comprising

a substrate; and

a heat conductive coating of the second example aspect of the invention.

The substrate may comprise material of high thermal conductivity.

According to a fourth example aspect of the disclosed embodiments there is provided an apparatus, comprising

a source of heat; and

a heat conductive coating of the second example aspect of the invention; or

a heat transfer apparatus of the third example aspect of the invention.

The apparatus may be an electronic device, a lighting device or a microprocessor.

According to a fifth example aspect of the disclosed embodiments there is provided a method, comprising:

receiving heat from a heat source of an electrical device into an ALD layer having at least one thin continuous layer of a first material; and

transferring received heat in the ALD layer by phonons farther from the heat source.

The ALD layer may comprise a heat conductive coating of the second example aspect of the invention.

The ALD layer may be provided with the method of the first example aspect of the invention.

According to a sixth example aspect of the disclosed embodiments there is provided an electronic apparatus, comprising:

a heat source; and

an ALD layer having at least one thin continuous layer of a first material, the apparatus being configured to transfer heat received into the ALD layer from the heat source by phonons in the ALD layer farther from the heat source.

The ALD layer may comprise a heat conductive coating of the second example aspect of the invention.

The ALD layer may be provided with the method of the first example aspect of the invention.

According to a seventh example aspect of the disclosed embodiments there is provided a heat transfer coating for the electronic apparatus of the sixth example aspect of the invention, comprising a substrate and an ALD layer deposited on the substrate, the ALD layer providing the ALD layer of the second example aspect of the invention.

According to an eighth example aspect of the disclosed embodiments there is provided a method of providing the heat transfer coating of the seventh example aspect of the invention, comprising depositing the ALD layer on the substrate.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The aspects of the disclosed embodiments will now be described, by way of example only, with reference to the accompanying drawings, in which:

FIG. 1 shows a schematic view of a device and a heat conductive coating according to an example embodiment of the invention;

FIG. 2 shows an enlarged schematic view of a device and a heat conductive coating according to an example embodiment of the invention;

FIG. 3 shows an enlarged schematic view of a device and a heat conductive coating and the principle of operation thereof according to an example embodiment of the invention;

FIG. 4 shows a schematic view of a heat conductive coating according to an example embodiment of the invention; and

FIG. 5 shows a method in accordance with an example embodiment of the invention.

### DETAILED DESCRIPTION

In the following description, Atomic Layer Deposition (ALD) technology is used as an example. The basics of an ALD growth mechanism are known to a skilled person. ALD is a special chemical deposition method based on the sequential introduction of at least two reactive precursor species to at least one substrate. Thin films grown by ALD are dense, pinhole free and have uniform thickness.

The at least one substrate is typically exposed to temporally separated precursor pulses in a reaction vessel to deposit material on the substrate surfaces by sequential self-saturating surface reactions. In the context of this application, the term ALD comprises all applicable ALD based techniques and any equivalent or closely related technologies, such as, for example MLD (Molecular Layer Deposition) technique.

A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be more complex. For example, the cycles can include three or more reactant vapor pulses separated by purging steps. All these deposition cycles form a timed deposition sequence that is controlled by a logic unit or a microprocessor.

The aspects of the disclosed embodiments seek to improve existing heat transfer solutions solution by use of ALD-applied nanolayers for providing heat conductive coatings on surfaces.

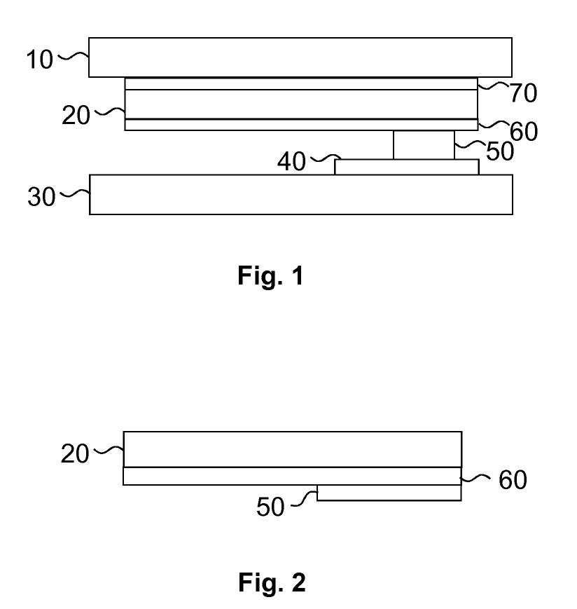

FIG. 1 shows a schematic view of a device and a heat conductive coating according to an example embodiment of the invention. In an example embodiment, the electronic device comprises for example a mobile phone, a smartphone, a tablet computer, or an e-book reader. FIG. 1 shows a circuit board 40, i.e. a printed wiring board, on which is mounted, or installed, an electronic component 50. The electronic component 50, in use, produces heat, which need be transferred away from the hot spot created by the electronic component 50. In an example embodiment, the electronic component is for example a microprocessor. FIG. 1 further shows a back cover 30 of the electronic device, such as a polymer cover, and a front cover 10 of the electronic device. In an example embodiment, the front cover 10 comprises a window assembly, for example a touch screen covered with glass.

FIG. 1 further shows a substrate 20 comprising a high thermal capacity substrate material such as magnesium. The substrate 20 is coated with a heat conductive coating 60. The heat conductive coating 60 is deposited on the substrate using ALD. In an example embodiment, the substrate 20 is coated on both, or all sides, thereof, and FIG. 1 accordingly shows a further heat conductive coating 70 deposited on the substrate using ALD. The substrate 20 with the heat conductive coating, is in an embodiment used in a different type of device, such as a lighting device, in order to efficiently transfer heat from the hot spot formed e.g. by light emitting diodes used as light sources. In a still further example embodiment, a separate substrate is not needed and a part of the device in which the heat transfer is needed functions as the substrate 20, i.e. the heat conductive coating 60 is deposited by ALD directly on a part of the device in which heat transfer is needed, for example on the same circuit board with the components of a microprocessor. In an example embodiment, the heat is transferred away from the hot spot into a heat sink.

FIG. 2 shows an enlarged schematic view of a device and a heat conductive coating according to an example embodiment of the invention. The electronic component 50 producing heat in use is shown, as well as the substrate 20 having a high thermal capacity and the heat conductive coating 60 deposited on the surface of the substrate using ALD.

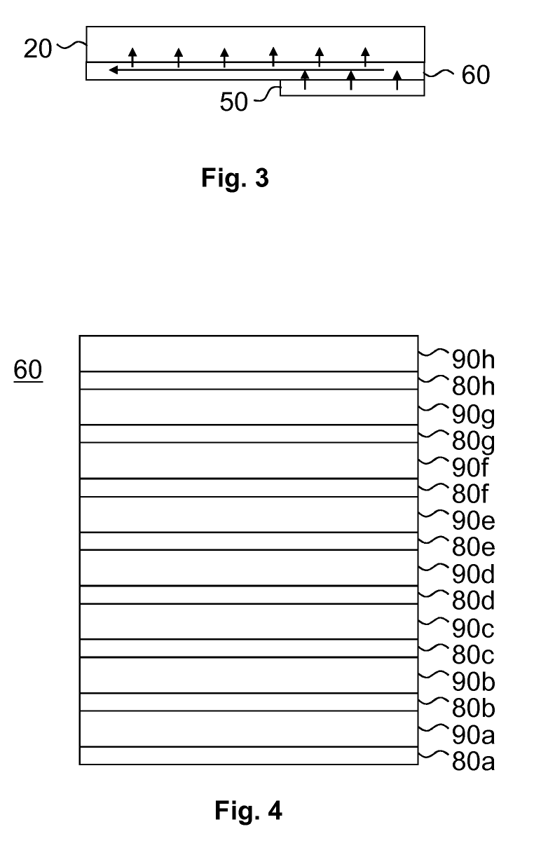

FIG. 3 shows an enlarged schematic view of a device and a heat conductive coating and the principle of operation thereof according to an example embodiment of the invention. The heat produced by the electronic component 50 is transferred to the heat conductive coating 60. The heat conductive coating 60 rapidly transfers heat from the hot spot produced by the electronic component 50 and at the same time the heat is transferred to the substrate 20 having a high thermal capacity. Accordingly, the heat produced is evenly spread and dissipated in a controlled manner. The heat transfer is especially efficient in a longitudinal direction of the heat conductive coating, i.e. in a direction parallel to the layers of the coating and the surface of the substrate. In an example embodiment, the layer or layers of the heat conductive coating 60 are conformal.

In a nanolayer, such as the heat conductive coating 60, heat transfer is at least in part carried out by vibrations in the crystal lattice known as phonons. The heat transfer properties of a thin film, such as the heat conductive coating 60, depend on the material or materials, i.e. the constituents or different layers of the coating and also on morphology of the layers and interfacial characteristics. It has been theorized that for high heat conductivity, i.e. quick and efficient heat transfer in the nanolayer, the propagation of phonons in the heat conductive coating should be unhindered, and the interference of phonons to one another should be minimized. This depends on the structure of the heat conductive coating 60. The heat transfer, and therethrough the thermal conductivity, of a material, for example a heat conductive coating, can be approximated to be dependent on the mean free path of the phonons in the material. The mean free path is affected by defects in the material, for example crystal or grain boundaries in the lattice structure, which define an upper limit for the heat conductivity of the material.

The inventors have established that a heat conductive coating 60 applied with ALD provides excellent heat conductivity and accordingly efficient heat transfer from the hot spot wherefrom heat needs be transferred and dissipated. The inventors have established that especially the heat transfer in the plane of the coating, i.e. parallel to the layers of the coating is efficient. The inventors have established that a thin continuous layer, i.e. a layer substantially free of defects and boundaries, deposited by ALD provides efficient in plane heat transfer and further established that a so-called nanolaminate comprising of subsequent layers of different materials deposited by ALD further provides efficient in plane heat transfer.

In an example embodiment, the heat conductive coating 60 comprises at least one thin continuous layer, in an example embodiment even a monolayer, of a single, or first, material deposited with ALD. In a further example embodiment the heat conductive coating comprises a number of monolayers of a single material, for example Al2O3, deposited with ALD, so that the thickness of the coating is for example up to about 250 nm, or even up to about 500 nm. In an example embodiment, the first material has a lower heat conductivity than the substrate, or surface, on which it is deposited, but as a thin continuous coating provides a more efficient heat transfer than an uncoated substrate. In an example embodiment, the thin continuous coating is amorphous.

However, a coating of single material deposited with ALD, while heat conductive, is not always the most effective. In a still further example embodiment, the heat conductive coating 60 comprises a nanolaminate deposited with ALD, i.e. subsequent thin continuous layers of two or more different materials, so that the thickness of the nanolaminate coating is for example up to about 250 nm, or even up to about 500 nm. In an example embodiment, the thin continuous coating of the first and/or the second material is amorphous.

The properties of coatings deposited by ALD can be carefully controlled. The deposited coating has a high uniformity and conformality providing the thin continuous layer. The structure of the material can be controlled to be amorphous, i.e. free of crystal characteristics. The properties of a continuous thin film, in an example embodiment also amorphous, deposited by ALD provide for good thermal conductivity.

In a preferred embodiment, the heat conductive coating comprises at least a first layer of a first material and at least a second layer of a second material. In an example embodiment, both the first and the second material have a lower thermal conductivity than the substrate, or surface, on which the coating is deposited, but still provide for a more efficient heat transfer than an uncoated surface due to phonon heat transfer. In a still further example embodiment the heat conductive coating comprises a nanolaminate structure, i.e. at least a first layer of a first material sandwiched between layers of second material. With such a nanolaminate, an increased heat transfer is realized. The layers of the nanolaminate provide an efficient in plane phonon heat transfer while the layer boundaries lessen the cross plane transfer which may result in decreased heat transfer capacity. In an example embodiment a nanolaminate with layer thicknesses of e.g. 2 and 13 nm and with for example 8 layers of each material resulting in a coating thickness of 125 nm is deposited by ALD. In an example embodiment the heat conductive coating 60 comprises amorphous metal oxide material. Suitable materials for the heat conductive coating comprise for example Aluminum oxide, Zinc oxide, Magnesium oxide, Hafnium oxide, Tantalum oxide, Zirconium oxide, Titanium oxide and combinations thereof.

FIG. 4 shows a schematic view of a heat conductive coating 60 according to an example embodiment of the invention. FIG. 4 shows a nanolaminate structure comprising layers 80a-h of a first material and layers 90a-h of a second material. In an example embodiment the number of layers of both the first and second material is the same, but a different number of layers of each material is readily envisaged. An example of the first and second material and thicknesses of the layers 80a-h and 90a-h is shown in the following table.

| Materials | Coating thickness ca. | Layer thicknesses ca. |
|---|---|---|
| Al₂O₃:ZnO | 125 nm | 8 * (2 nm Al₂O₃ + 13 nm ZnO) |
| Al₂O₃:ZnO | 125 nm | 8 * (13 nm Al₂O₃ + 2 nm ZnO) |

The following table shows the results of tests conducted with the heat conductive coatings according to example embodiments of the invention. The table shows some examples of the coating materials and thicknesses used and the resulting temperature measured at a hot spot, i.e. at a source of heat, from which the heat is to be transferred away. It is noted that the coating of a first, and in an example embodiment second, material deposited with ALD increases the heat transfer away from the hot spot, thus lowering the temperature at the hot spot.

| Coating material | Thickness ca. (nm) | Temperature ca. (° C.) |
|---|---|---|
| Without coating (reference) | | 77 |
| Al₂O₃ | 50 | 61 |
| Al₂O₃ | 125 | 66 |
| Al₂O₃ | 200 | 61 |
| HfO₂ | 50 | 63 |
| HfO₂ | 125 | 68 |
| HfO₂ | 200 | 73 |
| ZnO₂ | 50 | 74 |
| ZnO₂ | 125 | 62 |
| ZnO₂ | 200 | 62 |
| Al₂O₃ + HfO₂ | 125 (5 * 25) | 63 |
| Al₂O₃ + HfO₂ | 125 (25 * 5) | 59 |
| ZnO2 + Al₂O₃ | 125 (5 * 25) | 59 |
| ZnO2 + Al₂O₃ | 125 (25 * 5) | 57 |

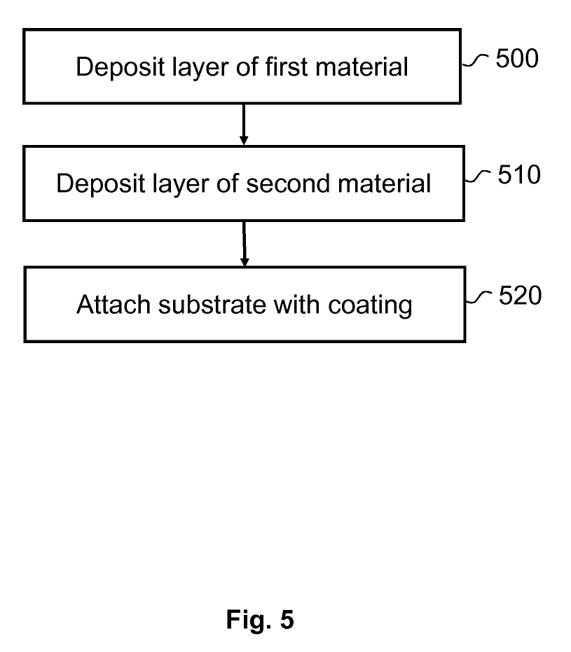

FIG. 5 shows a method in accordance with an example embodiment of the invention. At step 500 a layer of first material is deposited on a surface of for example a substrate in an ALD-process. The ALD-process is known to a skilled person. At step 510 a layer of second material is deposited on the layer of first material in an ALD-process. At step 520, the coated substrate, if separate substrate is used, is assembled to a device in which it is used. The steps 500 and 510 are repeated as needed for a nanolaminate structure if desired.

Without limiting the scope and interpretation of the patent claims, certain technical effects of one or more of the example embodiments disclosed herein are listed in the following: A technical effect of the invention is to provide a heat conductive coating with increased heat conduction. Another technical effect is providing a controlled heat distribution and dissipation from an electronic device.

It should be noted that some of the functions or method steps discussed in the preceding may be performed in a different order and/or concurrently with each other. Furthermore, one or more of the above-described functions or method steps may be optional or may be combined.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A method for providing a heat conductive coating on a surface of a substrate, comprising
depositing on the surface of the substrate at least one thin continuous layer of a first material by ALD; wherein
the first material has a lower heat conductivity than the substrate.

2. The method of claim 1, further comprising depositing at least one thin continuous layer of a second material by ALD on the at least one layer of a first material.

3. The method of claim 1, further comprising depositing alternating layers of the first and the second material.

4. The method of claim 1, wherein the thin continuous layer of the first material and/or the second material is amorphous.

5. The method of claim 1, wherein the substrate comprises material of high thermal conductivity.

6. The method of claim 1, wherein the first and/or the second material comprise amorphous metal oxide.

7. The method of claim 1, wherein the first and/or the second material comprise material chosen from a group comprising aluminum, magnesium, hafnium, titanium, tantalum and zirconium.

8. The method of claim 1, wherein the first material and/or the second material are chosen from a group comprising aluminum oxide, magnesium oxide, hafnium oxide, titanium oxide, tantalum oxide and zirconium oxide.

9. The method of claim 1, wherein the thickness of the coating is up to 250 nm.

10. A heat conductive coating, comprising
at least one thin continuous layer of a first material deposited by ALD on a surface of a substrate; wherein
the first material has a lower heat conductivity than the substrate.

11. The coating of claim 10, further comprising at least one thin continuous layer of a second material deposited by ALD on the at least one layer of a first material.

12. The coating of claim 10, further comprising alternating layers of the first and the second material deposited by ALD.

13. The coating of claim 10, wherein the thin continuous layer of the first material and/or the second material is amorphous.

14. The coating of claim 10, wherein the first and/or the second material comprise amorphous metal oxide.

15. The coating of claim 10, wherein the first and/or the second material comprise material chosen from a group comprising aluminum, magnesium, hafnium, titanium, tantalum and zirconium.

16. The coating of claim 10, wherein the first material and/or the second material are from a group comprising aluminum oxide, magnesium oxide, hafnium oxide, titanium oxide, tantalum oxide and zirconium oxide.

17. The coating of claim 10, wherein the thickness of the coating is up to 250 nm.

18. A heat transfer apparatus, comprising
a substrate; and
a heat conductive coating, comprising:
at least one thin continuous layer of a first material deposited by ALD on a surface of a substrate; wherein
the first material has a lower heat conductivity than the substrate.

19. The heat transfer apparatus of claim 18, wherein the substrate comprises material of high thermal conductivity.

20. An apparatus, comprising
a source of heat; and
a heat conductive coating, comprising:
at least one thin continuous layer of a first material deposited by ALD on a surface of a substrate; wherein
the first material has a lower heat conductivity than the substrate; or
a heat transfer apparatus, comprising a substrate and said heat conductive coating.

21. The apparatus of claim 20, wherein the apparatus is an electronic device, a lighting device or a microprocessor.

22. A method, comprising:
receiving heat from a heat source of an electrical device into an ALD layer having at least one thin continuous layer of a first material; and
transferring received heat in the ALD layer by phonons farther from the heat source.

23. The method of claim 22, wherein the ALD layer comprises a heat conductive coating, comprising:
at least one thin continuous layer of a first material deposited by ALD on a surface of a substrate; wherein
the first material has a lower heat conductivity than the substrate.

24. The method of claim 22, wherein the ALD layer is provided with a method for providing a heat conductive coating on a surface of a substrate, comprising
depositing on the surface at least one thin continuous layer of a first material by ALD, wherein
the first material has a lower heat conductivity than the substrate.

25. An electronic apparatus, comprising:
a heat source; and
an ALD layer having at least one thin continuous layer of a first material, the apparatus being configured to transfer heat received into the ALD layer from the heat source by phonons in the ALD layer farther from the heat source.

26. The electronic apparatus of claim 25, wherein the ALD layer comprises a heat conductive coating, comprising:
at least one thin continuous layer of a first material deposited by ALD on a surface of a substrate; wherein
the first material has a lower heat conductivity than the substrate.

27. The electronic apparatus of claim 25, wherein the ALD layer is provided with a method for providing a heat conductive coating on a surface of a substrate, comprising
depositing on the surface of the substrate at least one thin continuous layer of a first material by ALD; wherein
the first material has a lower heat conductivity than the substrate.

28. A heat transfer coating for the electronic apparatus of claim 25, comprising a substrate and an ALD layer deposited on the substrate, the ALD layer providing a heat conductive coating, comprising:
at least one thin continuous layer of a first material deposited by ALD on a surface of a substrate; wherein
the first material has a lower heat conductivity than the substrate.

29. A method of providing the heat transfer coating of claim 28, comprising depositing the ALD layer on the substrate.
